(19) United States
(12) Patent Application Publication
(10) Pub. No.: US 2006/0231880 A1
(43) Pub. Date: Oct. 19, 2006

(54) Semiconductor device and method of fabricating the same

(76) Inventors: Koji Yamakawa, Tokyo (JP); Soichi Yamazaki, Yokohama-shi (JP); Osamu Hidaka, Hachioji-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/399,313

(22) Filed: Apr. 7, 2006

(30) Foreign Application Priority Data
Apr. 15, 2005 (JP) 2005-119013

(51) Int. Cl. H01L 29/94; H01L 21/8242

(52) U.S. Cl. 257/306; 257/310; 438/244; 257/E27.086

(57) ABSTRACT

According to an aspect of the invention, there is provided a semiconductor device including a semiconductor substrate, and a capacitor formed above the semiconductor substrate by sandwiching a dielectric film between a lower electrode and upper electrode, wherein the upper electrode has a stacked structure including a first MOₓ type conductive oxide film (M is a metal element, O is an oxygen element, and x>0) having a crystal structure, and a crystal grain size of the first MOₓ type conductive oxide film is 5 to 100 nm.

### CROSS-REFERENCE TO RELATED APPLICATIONS

This application is based upon and claims the benefit of priority from prior Japanese Patent Application No. 2005-119013, filed Apr. 15, 2005, the entire contents of which are incorporated herein by reference.

### BACKGROUND OF THE INVENTION

1. Field of the Invention

The present invention relates to a semiconductor device and a method of fabricating the same and, more particularly, to a semiconductor device including a capacitor using a ferroelectric film and a method of fabricating the same.

2. Description of the Related Art

Recently, the development of a ferroelectric memory (FeRAM: Ferroelectric Random Access Memory), which is a nonvolatile memory using a thin ferroelectric film, is being advanced because of the advantages that the power consumption is low, micropatterning is possible, the operating speed is high, the endurance is high, nonvolatile properties are obtained, and random access is possible. This FeRAM is similar to a DRAM in which a capacitor portion is replaced with a ferroelectric material. Jpn. Pat. Appln. KOKAI Publication No. 2002-289809 discloses a semiconductor device including a ferroelectric capacitor.

In the FeRAM, a thin ferroelectric film such as PZT (Pb(ZrₓTi₁₋ₓ)O₃), BIT (Bi₄Ti₃O₁₂), or SBT (SrBi₂Ta₂O₉) is used in the capacitor portion. Each thin ferroelectric film has a crystal structure based on a perovskite structure having an oxygen octahedron as a basic structure, and has residual polarization used in nonvolatile recording of the FeRAM. Examples of the film formation process are sputtering, MOCVD, and a sol-gel process, each of which is compatible with the semiconductor memory fabrication process.

Since this thin ferroelectric film made of, e.g., PZT crystallizes on a lower electrode, the material and crystal structure of the lower electrode have a large influence. The material and structure of an upper electrode also have a large influence on the capacitor characteristics, and particularly have a direct influence on capacitor deterioration in the semiconductor memory fabrication process and on the reliability of the capacitor characteristics. All of the leakage characteristics, the C-V characteristics, the polarization characteristics, deterioration of the electrical characteristics with time, the retention characteristics, and the fatigue characteristics of the capacitor are also closely related to the electrode material and structure.

As the size of the capacitor decreases from the conventional several micron to submicron square, however, the process damage of, e.g., mask film CVD for capacitor RIE, capacitor RIE processing, and interlayer dielectric film CVD to the capacitor increases, so it is being desired to increase the process damage resistance by changing the upper electrode. As described above, to increase the degree of integration of the FeRAM using the ferroelectric material, it is necessary to improve the deterioration of the device reliability caused by the process damage resulting from the decrease in capacitor cell area.

When an SiO₂ film as a mask film for processing the capacitor is formed, a gas mainly containing hydrogen enters the interface between the capacitor insulating film and capacitor upper electrode, and the characteristics significantly deteriorate by the damage of, e.g., reduction and decomposition. In the conventional capacitor structure, the influence of this damage increases as the degree of integration increases and the chip size decreases. This makes it impossible to obtain a signal voltage necessary to operate the device.

Note that Jpn. Pat. Appln. KOKAI Publication No. 2002-261251 discloses a technique by which the upper electrode of a ferroelectric capacitor is formed by a stacked layer of SRO and amorphous IrOₓ having a controlled grain size. Jpn. Pat. Appln. KOKAI Publication No. 2002-110934 discloses a technique which prevents deterioration by controlling the crystal grain size of IrO₂ as the upper electrode of a ferroelectric capacitor. Japanese Patent No. 3545279 discloses a structure in which the upper electrode is made up of a plurality of IrOₓ layers formed by a plurality of film formation steps.

### BRIEF SUMMARY OF THE INVENTION

According to an aspect of the invention, there is provided a semiconductor device comprising: a semiconductor substrate; and a capacitor formed above the semiconductor substrate by sandwiching a dielectric film between a lower electrode and upper electrode, wherein the upper electrode has a stacked structure including a first MOₓ type conductive oxide film (M is a metal element, O is an oxygen element, and x>0) having a crystal structure, and a crystal grain size of the first MOₓ type conductive oxide film is 5 to 100 nm.

According to another aspect of the invention, there is provided a semiconductor device fabrication method comprising: forming, above a semiconductor substrate, a lower electrode film which forms a capacitor; forming, on the lower electrode film, a dielectric film which forms the capacitor; forming, on the dielectric film, a first MOₓ type conductive oxide film (M is a metal element, O is an oxygen element, and x>0) or ABOₓ type conductive oxide film (A and B are metal elements, O is an oxygen element, and x>0) serving as an upper electrode film which forms the capacitor; crystallizing the first MOₓ type conductive oxide film or ABOₓ type conductive oxide film by heating; and forming a second MOₓ type conductive oxide film (M is a metal element, O is an oxygen element, and x>0) on the crystallized first MOₓ type conductive oxide film or ABOₓ type conductive oxide film.

### BRIEF DESCRIPTION OF THE SEVERAL VIEWS OF THE DRAWING

FIG. 1 is a sectional view showing a memory cell of an FeRAM according to the first embodiment;

FIGS. 2A and 2B are SEM images of the surface and section, respectively, of a second upper electrode (IrOₓ film) of a capacitor structure according to the first embodiment;

FIG. 3 is a graph for explaining a method of forming the second upper electrode (IrOₓ film) according to the first embodiment;

FIG. 4 is a view showing the structure of a ferroelectric capacitor according to the second embodiment; and

FIG. 5 is a view showing the structure of a ferroelectric capacitor according to the third embodiment.

### DETAILED DESCRIPTION OF THE INVENTION

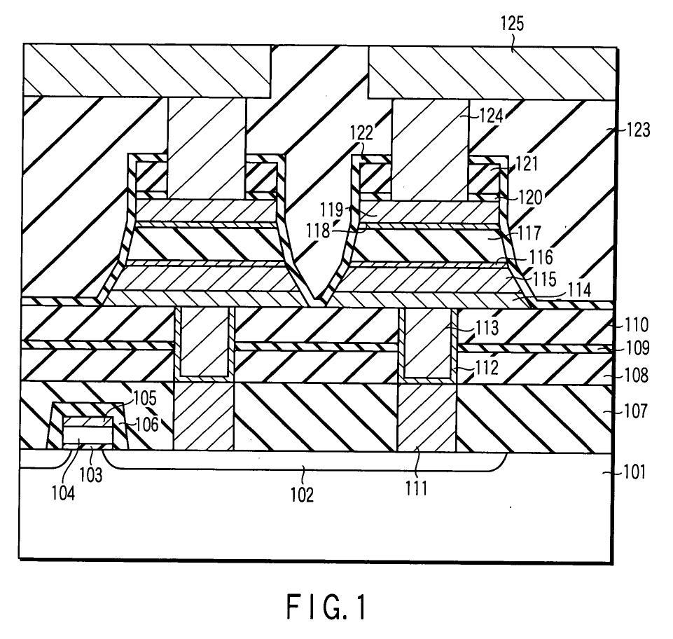

FIG. 1 is a sectional view of a memory cell of an FeRAM according to the first embodiment. Referring to FIG. 1, a trench type element isolation region (not shown) is formed on a p-type silicon (Si) substrate 101, and a MOS transistor is formed by a gate insulating film 103, a gate electrode (e.g., a polycide structure made up of a poly-Si film 104 and WSi₂ film 105) serving as a word line, a gate cap film and gate sidewall film 106 made of a silicon nitride film, and source/drain diffusion layers 102.

An interlayer dielectric film 107 (silicon oxide film) formed to surround this transistor is planarized, and interlayer dielectric films 108 (a silicon oxide film), 109 (a silicon nitride film), and 110 (a silicon oxide film) are formed on the interlayer dielectric film 107. In the interlayer dielectric films 107, 108, 109, and 110, contact plugs 111 and W plugs 113 which connect the activation region 102 of the transistor and barrier layers 114 of capacitors are formed. In addition, an anti-diffusion film (contact barrier film) 112 is formed to surround each plug 113.

Then, capacitors are formed on the interlayer dielectric film 110. Each capacitor is made up of the barrier layer (capacitor barrier film) 114, a lower electrode 115, an SRO film 116, a capacitor dielectric film 117, a first upper electrode (an SRO film: an ABOₓ perovskite type conductive oxide (A and B are metal elements, O is an oxygen element, and x>0)) 118, and a second upper electrode (an IrOₓ film: an MOₓ type conductive oxide (M is a metal element, O is an oxygen element, and x>0)) 119. The second upper electrode (IrOₓ film) 119 is formed by controlling its grain size. Also, on the second upper electrode 119, first and second mask films 120 and 121 for processing the upper electrode are formed so that they remain after the processing of the capacitor.

In addition, an anti-hydrogen film 122 is formed to surround the entire capacitor. In an interlayer dielectric film (silicon oxide film) 123 formed on the anti-hydrogen films 122, contacts 124 and interconnections 125 for connecting the upper electrodes of adjacent capacitors are formed.

In the first embodiment, the upper electrode has a stacked structure including the ABOₓ type perovskite structure conductive oxide (A and B are metal elements, O is an oxygen element, and x>0) and the MOₓ type conductive oxide (M is a metal element, O is an oxygen element, and x>0). The ABOₓ type conductive oxide is a typical material having a perovskite structure, in which A is a metal element mainly containing an alkaline earth metal element such as Pb, Ba, Sr, or Ca, and B is a metal element mainly containing Ti, Nb, Mg, Zr, Zn, Ta, W, or Mn. x is typically 3, and is variable in accordance with the excess or deficiency of oxygen. Examples of the ABOₓ type conductive oxide are SrRuO₃ (SRO), LaNiO₃ (LNO), (La, Sr)CoO₃, and YBCO (a superconductor). A stacked structure of SRO and IrOₓ as typical materials will be explained below.

First, an SRO film having a thickness of 1 to 50 nm is formed at room temperature by DC magnetron sputtering using an SRO ceramic target. After this film formation, a crystallization heat treatment is performed at 550° C. to 650° C. by RTO (Rapid Thermal Oxidation) or the like. The thickness is defined within the above range in order to supply sufficient oxygen to the interface between a PZT film and upper electrode. Defects such as oxygen deficiency in the interface between PZT and an upper electrode have large influence on the reducing process damage resistance, fatigue characteristic deterioration, retention deterioration, and imprint deterioration in the capacitor formation process to be performed later. Therefore, sufficient oxygen must be supplied.

An IrOₓ film is formed on the SRO film. The grain size of this IrOₓ film is 5 to 100 nm, preferably 10 to 40 nm. The IrOₓ film is formed by sputtering at a higher oxygen concentration (higher oxygen partial pressure) and a lower sputtering power than in the SRO film formation. Preferably, the sputtering power is set within the range of 0.1 to 1 W/cm² as a sputtering power density, and the ratio of the O₂ flow rate to the total sputtering gas flow rate is set at 50% (inclusive) to 100% (exclusive). A sputtering power density lower than 0.1 W/cm² is impractical because no stable discharge can be performed any longer, and the film formation rate decreases greatly. If the sputtering power density is higher than 1 W/cm², the grain size increases, and a large amount of oxygen must be supplied to form IrOₓ. This increases variations in film characteristics (e.g., the film thickness and resistance). The sputtering power density can be obtained from, e.g., the sputtering power, ambient, and target dimensions. For example, DC magnetron sputtering using an SRO target 300 mm in diameter is performed at 1 kW, room temperature, 0.5 Pa, and an oxygen flow rate ratio of 50% by using an argon-oxygen gas mixture. On the other hand, an IrOₓ film is formed on this SRO film by performing DC magnetron sputtering using an Ir target 300 mm in diameter at room temperature, 0.2 kW, Ar/O₂=20/80, and 0.5 Pa. The effects obtained by controlling the grain size in the structure of the IrOₓ layer will be described later.

Sufficient oxygen is supplied to the interface between SRO and PZT during SRO crystallization as the preceding stage, and the IrOₓ layer formed on SRO is given the effects of preventing capacitor deterioration and hydrogen diffusion in the hard mask CVD film formation process, capacitor RIE process, and reducing annealing to be performed later. Note that the grain size of the SRO film is as small as about 2 to 10 nm after crystallization is performed.

It is also possible to perform RTO at 500° C. after the IrOₓ film is formed. In this case, a flatness of 5 nm (Ra) is formed on the IrOₓ surface. This heat treatment densities IrOₓ, and further increases the reducing properties. In addition, the flatness increases the adhesion to the upper structure (the hard mask materials such as Al₂O₃ and SiOₓ), thereby preventing defects such as film peeling in the subsequence processes. The flatness also increases the surface area with respect to the upper structure. That is, the flatness increases an area serving as a sacrificial layer for suppressing the reducing damage caused by CVD, thereby effectively suppressing the damage. If the flatness is less than 2 nm, no effects of increasing the adhesion and the reduction process resistance can be obtained. If the flatness is 40 nm or more, the flatness of the upper electrode surface becomes too large. This makes the capacitor upper structure uneven, and interferes with the interconnecting step. Accordingly, the flatness, i.e., the surface roughness preferably falls within the range of Ra=2 to 25 nm.

As a modification, it is also possible to form an MOₓ type conductive oxide layer instead of the ABOₓ type conductive oxide layer described above, thereby giving the upper electrode a stacked structure of the MOₓ type conductive oxide and MOₓ type conductive oxide. In this case, similar to the ABOₓ type conductive oxide (SRO) described above, a 1- to 50-nm thick MOₓ type conductive oxide layer (e.g., IrOₓ) serving as a first upper electrode is formed, and a heat treatment is performed after that in order to supply sufficient oxygen to the interface to PZT. The heat treatment temperature is 550° C. to 650° C. Note that the thickness of the MOₓ type conductive oxide layer is defined in accordance with the oxygen amount to be supplied to the interface. In this case, the thickness is 1 to 40 nm, preferably 15 to 30 nm. If this thickness is too small, the characteristics deteriorate by damage caused by IrOₓ film formation to be performed later. If the thickness is too large, oxygen diffusion is interfered with by the formed IrOₓ layer even when oxygen is supplied to the upper electrode interface by RTO or the like. The structure and process of the IrOₓ layer formed as a second upper electrode on the first upper electrode are the same as described above.

Note that in the first and second upper electrodes in the stacked structure of the upper electrode, the following materials can be used as the MO type conductive oxide. This MOₓ type conductive oxide includes PtOₓ, IrOₓ, RuOₓ, RhOₓ, and OsOₓ as noble metal oxides, solid solutions and mixtures of these noble metal oxides, and materials mainly containing these noble metal oxides and also containing another element in the form of a dopant. Examples other than the noble metal oxides are conductive oxides such as ReO₃, VOₓ, TiOₓ, InOₓ, SnOₓ, ZnOₓ, and NiOₓ. Any of these conductive oxides can also be used as the MOₓ type conductive oxide.

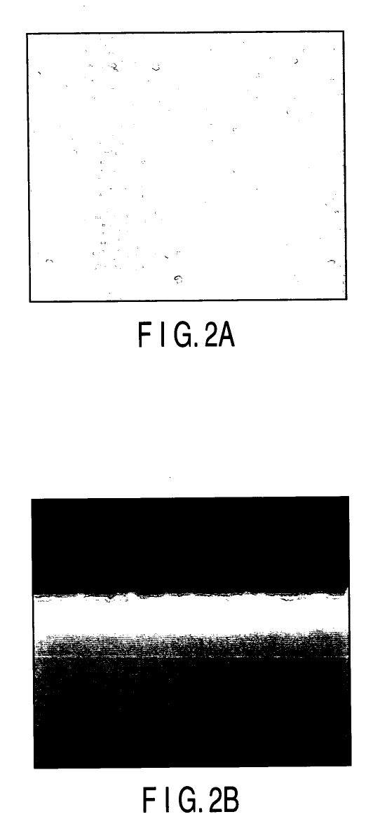

FIGS. 2A and 2B are SEM images of the surface and section, respectively, of the second upper electrode (IrOₓ film) 119 of the capacitor structure shown in FIG. 1. One characteristic feature is that the crystal structure of this film is no such columnar crystal as found in the prior art, but a fine crystal structure. The grain size is about 20 to 25 nm.

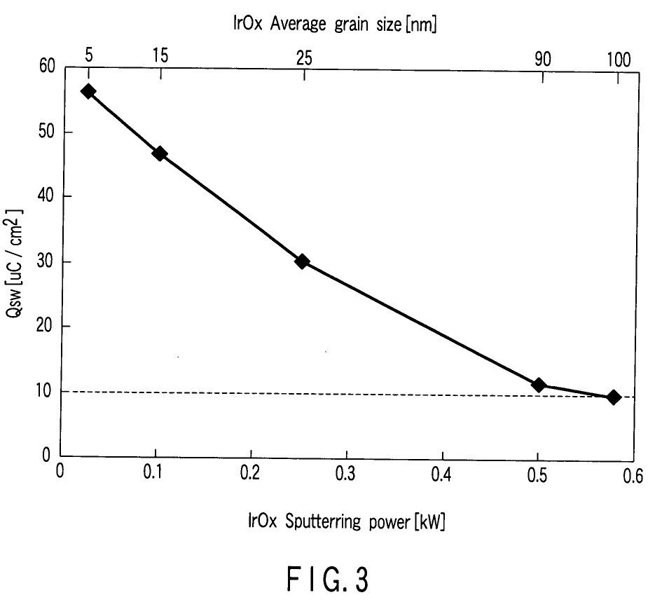

FIG. 3 is a graph for explaining a method of forming the second upper electrode (IrOₓ film) 119. The second upper electrode (IrOₓ film) 119 is formed by so-called reactive sputtering which uses an Ir target and by which oxygen is added during sputtering. As shown in FIG. 3, the grain size of IrOₓ can be controlled by changing the sputtering power during this sputtering film formation. Note that the sputtering power shown in FIG. 3 is merely a standard for determining the grain size of IrOₓ, so the grain size can also be controlled by adjusting another parameter. The IrOₓ layer is formed by performing DC magnetron sputtering using an Ir target 300 mm in diameter at room temperature, 0.2 kW, Ar/O₂=20/80, and 0.5 Pa.

FIG. 3 also shows the capacitor characteristic, i.e., the switching charge amount (the total amount of electric charge which flows when the polarization of a ferroelectric film is reversed, represented by Qsw), when IrOₓ films having various grain sizes are used as the second upper electrode 119. In the prior art, if the grain size of IrOₓ is larger than 100 nm, the Qsw becomes smaller than about 10 μC/cm². In the first embodiment, however, the crystal grain size of IrOₓ is controlled to be smaller that that. This increases the switching charge amount, and prevents deterioration of the capacitor characteristics.

The crystal grain size of IrOₓ of the second upper electrode 119 used as a capacitor of the FeRAM described earlier is 5 to 100 nm, desirably 10 to 40 nm. When the FeRAM capacitor is fabricated, after the formation of the capacitor constituting layers (the lower electrode, ferroelectric layer, and upper electrode), several heat treatment steps are performed before a final product form as a device is obtained. Examples are interlayer dielectric film plasma CVD (350° C. to 400° C.), capacitor RIE processing (250° C. to 350° C.), annealing (200° C. to 300° C.) during the interconnecting process, passivation film formation (350 to 400° C.), transistor characteristic recovering sinter annealing (200° C. to 350° C.), polyimide cure (300° C. to 400° C.), and packaging (250° C. to 350° C.). In some cases, the capacitor characteristics are improved by performing oxygen annealing at 450° C. to 650° C. after capacitors are processed, or after contact holes are formed to capacitors.

As described above, the IrOₓ grain size of the upper electrode is desirably 10 to 40 nm. The lower limit is thus set because it is difficult to completely suppress the reducing damage (particularly from the side surfaces) caused when capacitors are processed, and the reducing damage caused by interlayer dielectric film CVD, and it is desirable to perform a heat treatment at 450° C. to 600° C. after film formation since the film structure changes due to the thermal history in the step after the IrOₓ film is formed at room temperature.

After these heat treatments, grain growth occurs from the IrOₓ structure obtained by the film formation, thereby forming a structure in which the grain size is at least 5 nm or more. On the other hand, the increase in grain size reduces the effect of preventing hydrogen penetration which progresses from the reduction process through the grain boundaries of IrOₓ in the upper electrode. This further decreases the density of the grain boundaries, and increases variations in grain boundary density of IrOₓ with respect to the submicron capacitor. Consequently, the degree of damage to the capacitor changes from one cell to another, and this produces variations in characteristics. Also, in the direction of the film thickness, the grain size becomes larger than the thickness of the IrOₓ film, so the upper and lower portions of IrOₓ in the upper electrode are connected in a single grain boundary interface. This makes the structure weak against the process damage.

In addition, as shown in FIG. 3, as the grain size of the upper electrode IrOₓ increases, process deterioration of the polarization amount (e.g., the residual polarization amount, polarization reversal charge amount, and switching charge amount) when capacitors are formed increases. For an operation as the FeRAM, a polarization amount of 20 μC/cm² or more is desirable when the fatigue, retention, and imprint characteristics are taken into consideration. When the grain size of IrOₓ is 40 nm or less, a polarization amount of 20° C./cm² or more can be ensured.

By forming the IrOₓ film having this fine crystal structure with a small grain size, it is possible to efficiently prevent the penetration, into the capacitor, of a reducing gas produced when the second mask film 121 is formed, thereby preventing deterioration of the characteristics.

In addition, as the method of controlling the grain size of IrOₓ, it is possible to use a method which changes the oxygen amount added during sputtering. By increasing the oxygen amount (raising the oxygen partial pressure), the grain size of IrOₓ can be controlled from a few nm to 100 nm in the same manner as for the sputtering power, and similar effects can be obtained.

When the IrOₓ film of the upper electrode is to be formed in the FeRAM capacitor fabrication process according to this embodiment, a heat treatment is desirably performed at 400° C. to 600° C. after film formation by taking account of the thermal history in the subsequent steps. It is possible by this process to improve the crystallinity of IrOₓ, immobilize oxygen in IrOₓ, and stabilize the grain boundaries.

Also, this heat treatment forms, on the (upper) surface of the upper electrode IrOₓ, projections and recesses corresponding to the grain size of IrOₓ. The distance between the bottom of the recess and the top of the projection is 10 to 50 nm. These projections and recesses increase the surface area of the IrOₓ film per unit area of the upper electrode, and promote the effects on the reducing process to be performed later. It is also possible to improve the adhesion between IrOₓ of the upper electrode and the mask material such as a hard mask or resist mask used in capacitor processing.

When the Si oxide film to be used as a hard mask is formed by plasma CVD, the process sometimes reduces the IrOₓ film surface to form Ir, and deteriorates the adhesion to the oxide film. As a consequence, film peeling sometimes occurs in the subsequent steps. The heat treatment can prevent this problem.

As described previously, the capacitor cell size must be reduced with increasing degree of integration of the FeRAM which uses a ferroelectric film such as Pb(Zr, Ti)O₃ or an embedded memory including a ferroelectric capacitor which uses a ferroelectric as an insulating film. This reduction in memory cell size increases the influence of the backend damage. It is also necessary to ensure a signal amount required to operate the device without any problems, and at the same time reduce the capacitor area in the chip.

In the first embodiment, in the capacitor structure of the FeRAM or an embedded memory, the grain size of IrOₓ in the capacitor upper electrode is controlled. This makes it possible to obtain a sufficient capacitor signal amount even when the capacitor area is small. That is, it is possible to provide a semiconductor device which ensures the characteristics of a submicron capacitor using a ferroelectric film, and increases the process damage resistance. As described above, deterioration of the characteristics caused by the backend damage in the fabrication steps of a semiconductor device can be reduced, so the reliability of the semiconductor device improves.

In the second embodiment, the structure of a semiconductor memory device including a capacitor which uses an oxide ferroelectric and a method of fabricating the device will be described.

In this method, an upper electrode made of a noble metal oxide such as IrO₂ is made up of a plurality of layers different in microstructure, such as a grain size, and also different in oxygen permeability and hydrogen permeability. It is possible to ensure the ferroelectric film characteristics of a capacitor having this upper electrode structure, and suppress deterioration of the characteristics in, e.g., the CVD step, RIE step, interconnecting step, sintering step, and packaging step after the formation of the capacitor. Consequently, it is finally possible to improve the polarization characteristics (increase the signal amount), reduce the leakage current, improve the fatigue characteristics, improve the retention characteristics, and improve the imprint characteristics in the ferroelectric capacitor of the FeRAM.

The points of the structure and fabrication process of the semiconductor memory device according to the second embodiment will be explained below.

In the structure of this semiconductor memory device, the upper electrode is made of a noble metal oxide (e.g., IrO₂) including a plurality of layers. As the structure of this upper electrode made of the noble metal oxide, a noble metal oxide layer is made up of a plurality of layers different in grain size. Also, in the plurality of noble metal oxide layers forming the upper electrode made of the noble metal oxide, the grain size of a noble metal oxide close to a ferroelectric film is larger than those of other noble metal oxides. For example, the grain size of IrOₓ in a layer near the interface is 50 nm or more, and the grain size of IrOₓ in the upper layer portion is 5 to 100 nm, desirably 10 to 40 nm.

In the fabrication process, a noble metal oxide layer (e.g., IrOₓ) having a film thickness of less than 40 nm is formed at room temperature, and heat-treated in an oxygen-containing ambient to form a first noble metal oxide layer. After that, a second noble metal oxide layer having a film thickness of 40 nm or more is formed at a higher oxygen concentration or a lower film formation rate and sputtering power than in the film formation conditions of the first layer. The IrOₓ layer is formed by DC magnetron sputtering using an Ir target 300 mm in diameter at room temperature, 0.2 kW, Ar/O₂=50/50, and 0.5 Pa.

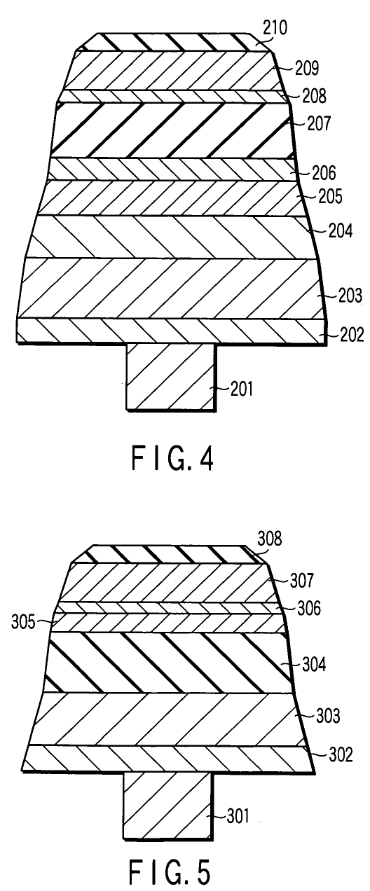

FIG. 4 is a view showing the structure of the ferroelectric capacitor according to the second embodiment. The fabrication steps of a ferroelectric memory using a thin PZT film will be explained below with reference to FIG. 4. First, a transistor is formed on a silicon (Si) substrate (not shown) by using the conventional process, thereby forming a CMOS structure. An insulating film made of, e.g., PSG or BPSG is formed in the transistor region by CVD, and the surface of the film is planarized by using CMP. An Si oxide film and SiN film are formed on the insulating film by CVD to form an underlying substrate.

Since a capacitor and an active area (source or drain) of the transistor are connected by a plug made of W or poly-Si, a plug 201 is formed beforehand. The formation of the plug 201 is done by using both blanket CVD and CMP.

A barrier metal layer 202 is formed to prevent oxidation of the plug surface during the formation of a ferroelectric film or in an in-oxygen annealing process for ensuring the capacitor characteristics after that. The barrier metal layer 202 is made of TiAlN (Ti/Al=0.7/0.3 (molar ratio)). The thickness is 50 nm. Note that the barrier metal layer need not be formed on the entire surface below a lower electrode, and it is also possible to form a barrier layer only on the plug after it is recessed, or to form a barrier layer on the entire surface below a lower electrode when it is formed. This slightly changes the whole process. In the former method, after the plug material is recessed by wet etching or dry etching, a film is formed by sputtering or the like to cover the entire surface of the plug, and the barrier material is left behind only on the plug in the CMP step after that. By using the barrier material in a portion of the plug, the thickness of the barrier film below a lower electrode can be decreased, thereby decreasing the total capacitor thickness. This facilitates the processing of a fine capacitor.

In the second embodiment, the barrier metal layer 202 is formed using DC magnetron sputtering on the surface which connects to the plug 201. On the barrier metal layer 202, an Ir layer 203 of a lower electrode is formed by sputtering. The film thickness is 100 nm. On the Ir layer 203, a 50-nm thick IrO₂ film 204 is formed by sputtering using oxygen. This sputtering is performed using DC magnetron sputtering by supplying a sputtering power of 1 kW to an Ir target 300 mm in diameter at Ar/O₂=30/70 and room temperature.

In an X-ray diffraction image immediately after the formation of these films, a structure close to amorphous was detected. When the morphology was observed, the structure was flat and had no characteristic grains. Note that before a thin PZT film as a ferroelectric film is formed, the crystallinity of IrO₂ may also be increased by a heat treatment process such as RTA (Rapid Thermal Anneal) at 550° C. In this case, a texture which has grown into the form of a column is observed, and the crystal of IrO₂ is found by X-ray diffraction. Alternatively, the IrO₂ film 204 may also be formed by high-temperature sputtering at 200° C. to 400° C. In this case, an IrO₂ crystal film is formed. The same texture is observed when RTA crystallization is performed after a thin PZT film is formed on a lower electrode.

The Ir layer 203 ensures the barrier properties of the plug 201 against the oxygen annealing step. On the other hand, the IrO₂ film 204 in the interface suppresses the diffusion and reaction to a PZT film 207 and prevents oxygen diffusion to the plug caused by the heat treatment, thereby preventing deterioration of the characteristics of the PZT film 207.

After the IrO₂ film 204 of about 50 nm thick is formed, a thin Pt film 205 is formed as a template. As when the Ir layer 203 is formed, the thin Pt film 205 is formed by DC magnetron sputtering at a temperature of about 200° C. to 400° C. The thickness of the thin Pt film 205 is about 10 to 50 nm. If the Ir layer 203 alone is used as an oxygen barrier layer, the Pt film 205 as a template is not inserted in some cases. This is so because Si diffuses from the Si plug 201, a silicide reaction with Pt occurs, or the shape of the Pt template deteriorates.

On the Pt layer 205, an SRO (SrRuO₃) film (a film mainly containing SRO) 206 is formed as a lower electrode. The SRO film 206 is formed by DC magnetron sputtering by using a conductive SRO ceramic target. Typical sputtering conditions are an Ar ambient, 0.5 Pa, no substrate heating, and 1 kW, and an amorphous SRO film about 10 to 50 nm thick is formed. After being formed by this sputtering, the SRO film 206 is crystallized by heating in an oxygen ambient at 550° C. to 650° C. by using RTA.

Then, a PZT film 207 is formed using sputtering. In this case, RF magnetron sputtering is used. The Pb amount of a PZT ceramic target is increased by about 10%. The target composition is Pb_{1.10}La_{0.05}Zr_{0.4}Ti_{0.6}O₃. A high-density PZT ceramic target has a high sputtering rate and also has a high environmental resistance to water and the like. Therefore, a ceramic sintered material having a theoretical density of 98% or more is used.

During sputtering, the rise of the substrate temperature caused by the plasma or bombardment of flying particles occurs. Consequently, evaporation of Pb from the Si substrate or re-sputtering occurs, so the Pb amount in the film readily decreases. The excess Pb added to the target compensates for this decrease, and promotes crystallization of the PZT film 207 during RTA. Since elements such as Zr, Ti, and La are entrapped in the film in substantially the same amounts as the target composition, a desirable composition amount ratio can be used.

If the electrical characteristics are unstable due to, e.g., the composition of the PZT film 207, the film formation conditions of the amorphous PZT film are changed. For example, to improve the structure and electrical characteristics of the PZT film to be crystallized, sputtering which supplies oxygen is used.

In the second embodiment, on the SRO film 206 as an undercoat, Ar gas alone is used to form an amorphous PZT film by performing RF magnetron sputtering for about 5 min at a gas pressure of 0.5 to 2.0 Pa and a power of 1.0 to 1.5 kW. The film thickness is 100 to 150 nm. The seed layer need not be an SRO film or PZT film, and it is also possible to use a thin Ti film, Zr film, Nb film, or Ta film about 2 to 5 nm thick. Also, before the PZT film formation, pre-sputtering is performed under the same sputtering conditions for about 10 to 30 min, in order to hold the state of the target surface, the temperature, and the environment in the chamber constant. The Pb amount and the structure and electrical characteristics after crystallization greatly change by this pre-sputtering.

In the structure in which the amorphous PZT film is formed on the Ir-based electrode formed on the plug 201 via the barrier metal layer 202, the PZT film 207 is crystallized by using RTA. When the crystal structure of the obtained film was checked by X-ray diffraction, a very strong reflection was obtained from the (111) plane in a perovskite phase.

Then, on the crystallized PZT film 207, a first IrO₂ film (a film mainly containing IrO₂) 208 is formed as an upper electrode by DC magnetron sputtering. The film formation conditions are, e.g., a sputtering power of 0.5 to 1 kW, Ar/O₂=about 70/30 to 50/50, and a pressure of 0.5 Pa. The film formation temperature is preferably room temperature or 100° C. or less. After the first IrO₂ film 208 having a thickness of 10 to 30 nm is formed, IrO₂ is crystallized by using RTO at 400° C. to 600° C., desirably 500° C. The purposes of this heat treatment are the crystallization of IrO₂ and the formation of a PZT/IrO₂ interface. The capacitor characteristics may deteriorate depending on the heat treatment conditions. Since the upper electrode has a low reactivity to a ferroelectric, a leak rarely occurs even when a heat treatment such as RTA is performed.

A second IrO₂ film 209 is then formed on the heat-treated, crystallized first IrO₂ film 208. The film thickness of the IrO₂ film 209 is 40 to 100 nm. Preferably, the sputtering power is set within the range of 0.1 to 1 W/cm² as a sputtering power density, and the ratio of the O₂ flow rate to the total sputtering gas flow rate is set at 50% (inclusive) to 100% (exclusive). A sputtering power density lower than 0.1 W/cm² is impractical because no stable discharge can be performed any longer, and the film formation rate decreases greatly. If the sputtering power density is higher than 1 W/cm², the grain size increases, and a large amount of oxygen must be supplied to form IrOₓ. This increases variations in film characteristics (e.g., the film thickness and resistance). The sputtering power density can be obtained from, e.g., the sputtering power, ambient, and target dimensions. As the film formation conditions, the temperature is desirably room temperature or 100° C. or less, and it is possible to use, e.g., a sputtering power of 0.1 to 0.5 kW, Ar/O₂=about 50/50 to 0/100, and a pressure of about 0.5 Pa. As the film formation conditions of the second IrO₂ film 209, it is important to use conditions under which the oxygen content in the film increases. When film formation is performed by sputtering, e.g., chemical sputtering (reactive sputtering) using an Ir target, the amount of oxygen entrapped in an IrO₂ film being formed increases if the sputtering power is decreased and the oxygen flow rate is increased.

Also, after the IrO₂ film 209 is formed, it is desirable to perform a heat treatment at 400° C. to 600° C. as in the first embodiment. This process improves the crystallinity of IrOₓ, and makes it possible to fix oxygen in IrOₓ and stabilize the grain boundaries. In addition, this heat treatment forms, on the (upper) surface of the upper electrode IrOₓ, projections and recesses corresponding to the grain size of IrOₓ.

Furthermore, an Si oxide film 210 as a mask material is formed on the IrO₂ film 209 by CVD. It is also possible to use an ordinary photoresist as a mask material when the FeRAM capacitor is processed by RIE (Reactive Ion Etching). However, a hard mask is often used because, e.g., if an ordinary photoresist is used, the selectivity to the resist cannot be raised during RIE processing, and it is impossible to perform high-temperature RIE for increasing the taper angle on the side surfaces of the capacitor.

After being formed, the hard mask is processed into the shape of a capacitor processing mask by RIE by using a photoresist. This RIE processing is performed at room temperature by using a halogen-based gas such as CHF₃ or CF₄. Then, the photoresist used in the hard mask RIE is removed by an ashing step, and the hard mask is used to process the IrO₂ films 208 and 209 of the upper electrode by RIE. A halogen gas is used in this RIE processing of the IrO₂ films 208 and 209. A gas mixture of, e.g., Cl₂, O₂ and Ar is used to process the IrO₂ films 208 and 209 of the upper electrode by RIE by raising the substrate temperature to a high temperature of 250° C. to 400° C.

The PZT film 207 is then processed by RIE at a high temperature by using a gas mixture based on halogen gases such as Cl₂, CF₄, O₂ and Ar. In addition, the SRO film 206, Pt film 205, IrO₂ film 204, and Ir film 203 as the materials forming the lower electrode are processed by RIE at a high temperature by using the same process. A gas mixture of Cl₂ and Ar is used for the SRO film 206 and Pt film 205. Although the thickness of the hard mask film reduces, the film maintains its shape until the processing of the lower electrode is completed. After the processing is completed, water rinsing is performed, and the capacitor processing step is completed.

After that, a backend step (interconnecting step) is performed to connect the capacitors, transistors, and interconnections. Although details of a multilayered interconnection formation step will be omitted, this step includes a series of steps such as insulating film formation (SiOₓ, a low-dielectric-constant film, an organic film, and the like are formed by, e.g., CVD, coating, and a heat treatment, or a barrier film such as SiN is formed), connecting hole/trench formation (oxide film RIE and the like), barrier film formation (formation of films of TiN, Ta, TaN, and the like by sputtering and CVD), interconnection formation (e.g., Al sputtering, Cu sputtering, plating, and annealing), and interconnection processing (e.g., Al RIE and Cu CMP). After the multilayered interconnections are formed, SiN is formed as a passivation film by CVD, and holes are formed in pad portions.

The ferroelectricity of the PZT film 207 formed by this process was checked by the hysteresis characteristic of charge amount Q−applied voltage V. Consequently, when 2.5V were applied, the charge amount was about 40 μC/cm² for a polarization amount of 2Pr (residual polarization×2). That is, the PZT film had an even polarization amount and even coercive electric field on the entire surface of the 8-inch Si wafer. The coercive voltage was also as low as about 0.6V. The capacitor sizes were 0.5 to 50 μm², and equal residual polarization amounts and equal switching charge amounts were obtained by these capacitors.

Also, the fatigue characteristics of the PZT capacitors were evaluated. When the fatigue characteristics were evaluated in an array equivalent to an area of 50 μm×50 μm, the polarization amount remained unchanged up to 1×10¹² cycles. In addition, the leakage current was as low as 10⁻⁷ A/cm² order when 2.5V was applied.

In the third embodiment, a method of forming a capacitor of a ferroelectric memory (FeRAM) will be described. In this method, ferroelectric memory capacitor formation steps begin after steps of forming an ordinary CMOS transistor.

FIG. 5 is a view showing the structure of the ferroelectric capacitor according to the third embodiment. First, a plug 301 for forming a contact to a source/drain portion of a transistor is formed. In this structure, a contact hole is formed by using RIE in an insulating film mainly containing SiO₂. Then, a Ti/TiN film is formed, and a W film is formed on TiN by blanket W-CVD. After the contact hole is filled, W and Ti/TiN as a barrier layer in portions except for the contact are removed by CMP.

After that, a 10-nm thick Ti film 302 as an adhesion film is formed. As a lower electrode, an Ir film 303 is formed by sputtering. The Ir film 303 has the effect of suppressing poor contact caused by oxidation of the upper surface of the plug in ferroelectric crystal film and electrode film formation steps (in an oxygen-containing ambient at 500° C. to 650° C.), or in an annealing step (in oxygen at 450° C. to 650° C.) of recovering a capacitor from the process damage. Ir has good oxygen barrier properties. To improve the crystallinity of the Ir film 303, sputtering film formation is preferably performed at a temperature of 200° C. to 400° C. The thickness of the Ir film 303 is preferably about 100 to 150 nm.

Then, a PZT crystal film 304 is formed by using MOCVD. This MOCVD has the advantages that the step coverage to the electrode structure is high, the composition controllability is high, a uniform high-quality film is obtained in a large area, the film formation rate is high, and the thickness of a ferroelectric film can be decreased (a low-voltage operation is possible). Typical examples of PZT materials used in MOCVD are Pb(dpm)₂ as a Pb source, Zr(dpm)₄ and Zr(O-tC₄H₉)₄ as Zr sources, and Ti(O-iC₃H₇)₄ and Ti(O-iC₃H₇)₂(dpm)₂ as Ti sources. These materials are mixed with THF (tetrahydrofuran) and used in a solution vaporization method. Various types of vaporizers are usable, so the source materials are vaporized by using, e.g., a vaporizer which sprays a solution by using ultrasonic waves, a vaporizer which sprays a solution against a hotplate, or a vaporizer which uses an atomizer. The substrate temperature is preferably about 600° C., although it also depends on the material. N₂O or O₂ is supplied as an oxidizer at the same time. Crystallization occurs in-situ, so a PZT <111> crystal film can be obtained on the Ir film 303 described above.

On the crystallized PZT film 304, an SRO film 305 as an upper electrode and as a hard mask is formed. Similar to the Ir film 303 of the lower electrode, the SRO film 305 is obtained by forming an amorphous film by sputtering, and crystallizing the film at 600° C. to 700° C. in an RTO process. The thickness is desirably about 5 to 50 nm.

Similar effects can also be obtained by forming the following conductive oxide electrodes instead of SRO.

SRTO (Sr(Ru, Ti)O₃: Ti=0 to 50 mol %)

SRTO is a solid solution of SRO and STO (SrTiO₃), and the resistivity increases as the addition amount of STO increases. SRTO can be used as an electrode material until the STO content is about 50%. The reduction resistance is higher than that of SRO.

CaRuO₃, (Sr, X)RuO₃, or the Like

This material is a conductive oxide like SRO, and has a crystal structure in which SRO is substituted with Sr or Ca. A material in which Sr is partially substituted with Ba or Ca can also be used as an electrode material.

SrIrO₃

This material is a conductive oxide having a low resistivity in a stoichiometric composition. This material is formed by the SRO constituent elements and Ir used in the lower electrode.

BaPbO₃, BaPb₁₋ₓBiₓO₃

This material is a conductive oxide by which the temperature coefficient of the resistivity is positive. The material to which Bi is doped also shows superconductivity.

LSCO ((La, Sr)CoO₃))

LSCO is a conductive oxide having the same perovskite structure as SRO and PZT. There are many examples of uses as the electrode of a PZT capacitor.

LNO (LaNiO₃)

LNO is a conductive oxide having the same perovskite structure as SRO and PZT. There are many examples of uses as the electrode of a PZT capacitor.

Oxide Superconducting Materials and the Like

High-temperature oxide superconducting materials such as YBCO and a Bi compound are used. An example is YbaCuO.

Semiconductor Perovskite Oxide

A semiconductor obtained by forming STO in a reducing ambient or a semiconductor obtained by performing a reducing heat treatment on STO is used. Alternatively, a semiconductor obtained by doping a donor element such as La or Nb or an acceptor element such as Fe or Al to STO is used. As the base material, it is also possible to use CaTiO₃, BaTiO₃, and their solid solutions, instead of STO.

The capacitor characteristics can be improved by inserting any of these materials between the IrO₂ upper electrode and the ferroelectric film such as PZT in this embodiment. As the film formation method, it is possible to use, e.g., laser abrasion, a PVD process such as EB vapor deposition, a sol-gel process, a CSD process such as MOD, and a CVD process such as MOCVD, instead of sputtering processes (e.g., DC magnetron sputtering, RF magnetron sputtering, helicon sputtering, and ion beam sputtering). The crystallization methods are in-situ crystallization by which a film is formed at a high temperature, and ex-situ crystallization by which a film is formed and then crystallized by using RTP or the like. It is of course also possible to use these film formation methods in, e.g., lower electrode formation, ferroelectric film formation, and upper electrode film formation, as well as in the upper electrode ABOₓ formation.

Then, on the SRO film 305 on the crystallized PZT film 304, a first IrO₂ film (a film mainly containing IrO₂) 306 is formed as an upper electrode by DC magnetron sputtering. The film formation conditions are, e.g., a sputtering power of 0.5 to 1 kW, Ar/O₂=about 50/50 to 70/30, and a pressure of 0.5 Pa. The film formation temperature is preferably room temperature or 100° C. or less. After the first IrO₂ film 306 having a thickness of 10 to 30 nm is formed, IrO₂ is crystallized by using RTO at 400° C. to 600° C., desirably 500° C., thereby obtaining a grain size of 100 nm or more.

The purposes of this heat treatment process are the crystallization of IrO₂ and the formation of a PZT/IrO₂ interface. The capacitor characteristics may deteriorate depending on the heat treatment conditions. Since the upper electrode has a low reactivity to a ferroelectric, a leak rarely occurs even when a heat treatment process such as RTA is performed.

A second IrO₂ film 307 is then formed on the heat-treated, crystallized first IrO₂ film 306. The IrO₂ film 307 has a film thickness of 40 to 100 nm, and a grain size of 5 to 100 nm, desirably 10 to 40 nm. Preferably, the sputtering power is set within the range of 0.1 to 1 W/cm² as a sputtering power density, and the ratio of the O₂ flow rate to the total sputtering gas flow rate is set at 50% (inclusive) to 100% (exclusive). A sputtering power density lower than 0.1 W/cm² is impractical because no stable discharge can be performed any longer, and the film formation rate decreases greatly. If the sputtering power density is higher than 1 W/cm², the grain size increases, and a large amount of oxygen must be supplied to form IrOₓ. This increases variations in film characteristics (e.g., the film thickness and resistance). The sputtering power density can be obtained from, e.g., the sputtering power, ambient, and target dimensions. As the film formation conditions, the temperature is desirably room temperature or 100° C. or less, and it is possible to use, e.g., a sputtering power of 0.2 to 0.5 kW, Ar/O₂=about 50/50 to 0/100, and a pressure of about 0.5 Pa. As the film formation conditions of the second IrO₂ film 307, it is important to use conditions under which the oxygen content in the film increases. When film formation is performed by sputtering, e.g., chemical sputtering (reactive sputtering) using an Ir target, the amount of oxygen entrapped in an IrO₂ film being formed increases if the sputtering power is decreased and the oxygen flow rate is increased.

Also, after the IrO₂ film 307 is formed, it is desirable to perform a heat treatment at 400° C. to 600° C. as in the first embodiment. This process improves the crystallinity of IrOₓ, and makes it possible to immobilize oxygen in IrOₓ and stabilize the grain boundaries. In addition, this heat treatment forms, on the (upper) surface of the upper electrode IrOₓ, projections and recesses corresponding to the grain size of IrOₓ.

Furthermore, an Si oxide film 308 as a mask material is formed on the IrO₂ film 307 by CVD. It is also possible to use an ordinary photoresist as a mask material when the FeRAM capacitor is processed by RIE (Reactive Ion Etching). However, a hard mask is often used because, e.g., if an ordinary photoresist is used as a mask material, the selectivity to the resist cannot be raised during RIE processing, and it is impossible to perform high-temperature RIE for increasing the taper angle on the side surfaces of the capacitor.

Normally, when an FeRAM capacitor using a noble metal is to be processed by RIE, the taper angle of the capacitor is decreased because Pt, Ir, or the like is difficult to process (the formation of a gas seed having a high vapor pressure is difficult, and a noble metal fence is formed on the capacitor side surfaces). However, this makes the formation of fine capacitors difficult. To realize a high-density FeRAM, therefore, processing of a capacitor having a large taper angle is necessary. One method is to use high-temperature RIE.

After being formed, the hard mask is processed into the shape of a capacitor processing mask by RIE by using a photoresist. This RIE processing is performed at room temperature by using a halogen-based gas such as CHF₃ or CF₄. Then, the photoresist used in the hard mask RIE is removed by an ashing step, and the hard mask is used to process the IrO₂ films 307 and 306 of the upper electrode by RIE. A halogen gas is used in this RIE processing of the IrO₂ films 307 and 306. A gas mixture of, e.g., Cl₂, O₂, and Ar is used to process the IrO₂ films 307 and 306 of the upper electrode by RIE by raising the substrate temperature to a high temperature of 250° C. to 400° C.

The PZT film 304 is then processed by RIE at a high temperature by using a gas mixture based on halogen gases such as Cl₂, CF₄, O₂ and Ar. In addition, the Ir film 303 as the material forming the lower electrode is processed by RIE at a high temperature by using the same process. A gas mixture of Cl₂ and Ar is used for the Ti film 302. Although the thickness of the hard mask film reduces, the film maintains its shape until the processing of the lower electrode is completed. After the processing is completed, water rinsing is performed, and the capacitor processing step is completed.

After that, a backend step (interconnecting step) is performed to connect the capacitors, transistors, and interconnections. Although details of a multilayered interconnection formation step will be omitted, this step includes a series of steps such as insulating film formation (SiOₓ, a low-dielectric-constant film, an organic film, and the like are formed by, e.g., CVD, coating, and a heat treatment, or a barrier film such as SiN is formed), connecting hole/trench formation (oxide film RIE and the like), barrier film formation (formation of films of TiN, Ta, TaN, and the like by sputtering and CVD), interconnection formation (e.g., Al sputtering, Cu sputtering, plating, and annealing), and interconnection processing (e.g., Al RIE and Cu CMP). After the multilayered interconnections are formed, SiN is formed as a passivation film by CVD, and holes are formed in pad portions.

The ferroelectricity of the PZT film 304 formed by this process was checked by the hysteresis characteristic of charge amount Q−applied voltage V. Consequently, when 2.5V was applied, the charge amount was about 40 μC/cm² for a polarization amount of 2Pr (residual polarization×2). That is, the PZT film had an even polarization amount and even coercive electric field on the entire surface of the 8-inch Si wafer. The coercive voltage was also as low as about 0.6V. The capacitor sizes were 0.5 to 50 μm, and equal residual polarization amounts and equal switching charge amounts were obtained by these capacitors.

Also, the fatigue characteristics of the PZT capacitors were evaluated. When the fatigue characteristics were evaluated in an array equivalent to an area of 50 μm×50 μm, the polarization amount remained unchanged up to 1×10¹² cycles. In addition, the leakage current was as low as 10⁻⁷ A/cm² when 2.5V was applied.

Note that ferroelectric films include, in addition to the PZT film, ferroelectric composite oxides such as SBT (SrBi₂Ta₂O₉) and a material obtained by doping Nb to it, BLT ((Bi, La)₄Ti₃O₁₂), and PZT and PLZT to which various elements are doped. As the lower electrode, it is also possible to use Pt, Ru, RuO₂, IrO₂, or a stacked structure or mixture of these materials, instead of Ir. The film thickness is also not limited, provided that the plug does not oxidize during the process.

Note also that the noble metal oxide material forming the upper electrode is not limited to IrO₂. The same effects can be expected by noble metal oxides such as RuO₂, RhO₂, and PtOₓ (an MOₓ type conductive oxide), mixtures of these oxides, materials mainly containing these oxides, and mixtures of these oxides with Pt.

In the second and third embodiments as described above, when a capacitor for increasing the capacity and integration degree of the FeRAM is to be micropatterned, it is possible to increase the resistance against the damage caused by the processes such as the CVD step, RIE step, and sintering step, without deteriorating the single-film characteristics of the capacitor. In recent FeRAM capacitors, PZT (Pb(Zr, Ti)O₃) or SBT (SrBi₂Ta₂O₉) is used as a thin ferroelectric film, a noble metal, noble metal oxide, or conductive oxide such as Pt, Ir, IrO₂, Ru, or RuO₂ is used as a lower electrode, and a noble metal, a noble metal oxide, or a conductive composite oxide such as a perovskite structure, e.g., Pt, Ir, IrO₂, Ru, RuO₂, SrRuO₃, LaNiO₃, or (La, Sr)CoO₃, is used as an upper electrode. IrO₂ is widely used as the upper electrode of the PZT film. The above embodiments improve the method of forming this IrO₂, thereby improving the initial capacitor characteristics (the single-film characteristics of the PZT capacitor), and increasing the resistance against the damage caused by the processes such as the CVD step, RIE step, and sintering step.

More specifically, the IrO₂ upper electrode is formed as an IrO₂ film made up of a plurality of layers by multi-step film formation, rather than by batch film formation. As a structure, the process damage resistance is ensured by forming the IrO₂ upper electrode by a plurality of layers different in grain size. Also, to improve the capacitor single-film characteristics, an interface is formed between PZT and IrO₂ by forming an IrO₂ film in a state in which sufficient oxygen can be supplied to this interface. By these processes, an IrO₂ upper electrode applicable to a micro capacitor whose capacitor size is on the order of submicrons is formed.

As described above, the second and third embodiments use the structure in which the noble metal oxide in the upper electrode formed on the ferroelectric film is made up of a plurality of layers different in grain size. After a first noble metal oxide film close to the ferroelectric film is formed, a favorable electrode interface is formed by a heat treatment, and a second noble metal oxide layer is formed under different film formation conditions.

By thus improving the method of forming the noble metal oxide (e.g., IrO₂) forming the upper electrode, it is possible to improve the initial capacitor characteristics (the single-film characteristics of the PZT capacitor), and increase the resistance against the damage caused by the processes such as the CVD step, RIE step, and sintering step. Since an IrO₂ upper electrode applicable to a submicron-size capacitor is formed, it is possible to provide a semiconductor device which ensures the characteristics of a submicron capacitor using a ferroelectric film, and increase the process damage resistance.

The embodiments of the present invention can provide a semiconductor device which increases the process damage resistance of a capacitor, and a method of fabricating the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate; and
a capacitor formed above the semiconductor substrate by sandwiching a dielectric film between a lower electrode and upper electrode,
wherein the upper electrode has a stacked structure including a first MOₓ type conductive oxide film (M is a metal element, O is an oxygen element, and x>0) having a crystal structure, and a crystal grain size of the first MOₓ type conductive oxide film is 5 to 100 nm.

2. The device according to claim 1, wherein the stacked structure has the first MOₓ type conductive oxide film, and an ABOₓ type conductive oxide film (A and B are metal elements, O is an oxygen element, and x>0) formed below the first MOₓ type conductive oxide film and having a crystal structure.

3. The device according to claim 1, wherein the stacked structure has the first MOₓ type conductive oxide film, and a second MOₓ type conductive oxide film (M is a metal element, O is an oxygen element, and x>0) formed below the first MOₓ type conductive oxide film and having a crystal structure, and
a crystal grain size of the second MOₓ type conductive oxide film is larger than that of the first MOₓ type conductive oxide film.

4. The device according to claim 2, wherein the ABOₓ type conductive oxide film includes SRO.

5. The device according to claim 2, wherein the first MOₓ type conductive oxide film includes IrOₓ.

6. The device according to claim 3, wherein the first MOₓ type conductive oxide film and the second MOₓ type conductive oxide film include IrOₓ.

7. The device according to claim 2, wherein a crystal grain size of the ABOₓ type conductive oxide film is smaller than that of the first MOₓ type conductive oxide film.

8. The device according to claim 1, wherein a surface of the first MOₓ type conductive oxide film has an uneven shape having surface roughness Ra=2 to 25 nm.

9. A semiconductor device fabrication method comprising:
forming, above a semiconductor substrate, a lower electrode film which forms a capacitor;
forming, on the lower electrode film, a dielectric film which forms the capacitor;
forming, on the dielectric film, a first MOₓ type conductive oxide film (M is a metal element, O is an oxygen element, and x>0) or ABOₓ type conductive oxide film (A and B are metal elements, O is an oxygen element, and x>0) serving as an upper electrode film which forms the capacitor;
crystallizing the first MOₓ type conductive oxide film or ABOₓ type conductive oxide film by heating; and
forming a second MOₓ type conductive oxide film (M is a metal element, O is an oxygen element, and x>0) on the crystallized first MOₓ type conductive oxide film or ABOₓ type conductive oxide film.

10. The method according to claim 9, wherein an oxygen concentration when the second MOₓ type conductive oxide film is formed is higher than that when the first MOₓ type conductive oxide film or ABOₓ type conductive oxide film is formed.

11. The method according to claim 9, wherein a sputtering power when the second MOₓ type conductive oxide film is formed is lower than that when the first MOₓ type conductive oxide film or ABOₓ type conductive oxide film is formed.

12. The method according to claim 9, wherein the second MOₓ type conductive oxide film is formed by reactive sputtering using a target made of a metal M, such that a sputtering power density is 0.1 to 1 W/cm², and a ratio accounted for by an O₂ flow rate in a total sputtering gas flow rate is 50% (inclusive) to 100% (exclusive).
